(19) United States
(12) Patent Application Publication
(10) Pub. No.: US 2017/0179359 A1
(43) Pub. Date: Jun. 22, 2017

(54) A WAVELENGTH CONVERTING ELEMENT, A LIGHT EMITTING MODULE AND A LUMINAIRE

(71) Applicant: PHILIPS LIGHTING HOLDING B.V., EINDHOVEN (NL)

(72) Inventors: Manuela LUNZ, EINDHOVEN (NL); Loes Johanna Mathilda KOOPMANS, EINDHOVEN (NL); Patrick ZUIDEMA, EINDHOVEN (NL); Hendrik Johannes Boudewijn JAGT, EINDHOVEN (NL)

(21) Appl. No.: 15/116,866

(22) PCT Filed: Jan. 30, 2015
(86) PCT No.: PCT/EP2015/051976

§ 371 Date: Aug. 5, 2016

(30) Foreign Application Priority Data
Feb. 11, 2014 (EP) 14154700.0

(51) Int. Cl. H01L 33/64; F21V 29/70; F21V 9/08; F21V 3/00; H01L 33/50; H01L 25/075

(52) U.S. Cl. CPC H01L 33/642; H01L 33/502; H01L 33/507; H01L 25/0753; F21V 9/08; F21V 3/00; F21V 29/70

(57) ABSTRACT

A wavelength converting element (100), a light emitting module and a luminaire are provided. The wavelength converting element comprises a luminescent element (104) and a light transmitting cooling support (112). The luminescent element comprises a luminescent material (102) and a light transmitting sealing envelope (108) for protecting the luminescent material against environmental influences. The sealing envelope has a first thermal conductivity. The cooling support has a second thermal conductivity that is at least two times the first thermal conductivity. The cooling support comprises a first surface (113) and the sealing envelope comprises a second surface (105). The first surface and the second surface face towards each other. The first surface is thermally coupled to the second surface for allowing through the second surface a conduction of heat towards the cooling support to enable a redistribution of the heat generated in the luminescent element.

### FIELD OF THE INVENTION

The invention relates to a wavelength converting element for converting light of a first color to light of another color.

The invention further relates to light emitting module and a luminaire.

### BACKGROUND OF THE INVENTION

Phosphor conversion is often used for Light Emitting Diodes (LEDs) and modules which comprise LEDs to generate white light or light of a specific color that cannot be efficiently generated directly by a LED. However, some of the currently used phosphors have a quite broad emission that extends beyond the sensitivity of the eye and hence photons “in-visible” to the human eye are generated, which lead to a decrease of the efficacy of the LED modules. In order to improve the efficacy, narrow-band red and green emitters are considered for such LED modules. However, most narrow-band emitters suffer from: a) sensitivity to oxygen or water, i.e. leading to permanent degradation; b) high temperatures, i.e. decrease in performance above 100-120° C. and decreased stability; and c) high blue fluxes, which can also lead to a decrease in performance and accelerated degradation. To prevent the high blue fluxes, the phosphor is often placed at a distance away from the LED to decrease the flux density. When the phosphor is not directly provided on the LED it is also less influenced by a temperature of the LED die. However, the phosphor can still become relatively warm because it converts also a portion of the absorbed light towards heat as the result of the Stokes Shift of the phosphor. When the phosphor is sensitive to oxygen or water, it is often hermetically, or semi-hermetically sealed (which means that a relatively low, well-controlled, amount of air or moisture is able to penetrate through the seal). For example, document US2013/0094176A1, which is incorporated by reference, discloses embodiments of hermetically sealed phosphors. The material of the disclosed seals has not only the function to seal the phosphors, but also the function to support the phosphor and to provide a strong enough structure for the hermetically sealed phosphors. In other words, the sealing layers are relatively thick because they are also the structural features that shape the hermetically sealed phosphor and prevent, for example, that they break of fall. However, a problem of most seals is that the material of the seals has a relatively low thermal conductivity—in combination with a relatively thick sealing layer it results in an overheating of the phosphor material. In particular, at particular sections of the phosphor material on which a relatively large amount of light impinges more light is converted towards light of another color and as such these sections may become too hot. Patents have been applied for seals that are manufactured of, for example, a ceramic material that is transparent or translucent and that has a relatively high thermal conductivity. However, it has been seen that it is relatively difficult to manufacture such seals with high enough accuracy at an affordable price.

Document US2014/0021503 discloses a semiconductor light emitting device having a phosphor layer sealed within a glass envelope operating as a luminescent element. The glass envelope is supported by a resin layer comprising ceramic fine particles. The fine particles increase the heat conductivity of the resin so that a heat increase caused by the phosphor layer can be suppressed.

### SUMMARY OF THE INVENTION

It is an object of the invention to provide a wavelength converting element that has a better thermal management.

An aspect of the invention provides a wavelength converting element. Another aspect of the invention provides a light emitting module. A further aspect of the invention provides a luminaire. Advantageous embodiments are defined in the dependent claims.

A wavelength converting element in accordance with the first aspect of the invention comprises a luminescent element and a light transmitting cooling support. The luminescent element comprises a luminescent material and a light transmitting sealing envelope for protecting the luminescent material against environmental influences, such as, for example air and/or moisture. The luminescent material is configured to absorb a portion of impinging light and to convert a portion the absorbed light towards light of another color. The sealing envelope comprises two layers of glass in between which the luminescent material is provided. The (material of) the sealing envelope has a first thermal conductivity. The cooling support has a second thermal conductivity that is at least two times the first thermal conductivity. The cooling support comprises a first surface and the sealing envelope comprises a second surface. The first surface and the second surface face towards each other. The first surface is thermally coupled to the second surface for allowing through the second surface a conduction of heat towards the cooling support to enable a redistribution of the heat generated in the luminescent element.

The thermal management of the luminescent element is improved by the cooling support. The cooling support has a relatively high thermal conductivity and, therefore, when it receives heat from the luminescent element, it spreads the heat through the cooling support (and, as such through the wavelength converting element as a whole). Thereby it is prevented that at specific hot spots the luminescent element becomes too hot. Furthermore, because the heat is better spread through the whole wavelength conversion element, at an interface between the wavelength conversion element the heat is provided to the environment of the wavelength conversion element via a relatively large surface and, thus, a better cooling can be obtained. In particular, when an object (e.g. the luminescent element) has only some small hot spots and is relatively cool at most of its surface, less heat can be provided to the environment than in a situation wherein the heat of the hotspots is distributed along the whole surface. Furthermore, the cooling support may act as a heat conductor towards a heat sink to which the wavelength conversion element may be coupled thereby providing a thermal path to the heat sink with a relatively low thermal resistance.

The second surface (i.e. one side of the sealing envelope) faces the first surface (i.e. a surface of the cooling support). In particular about the entire second surface the sealing envelope is thermally coupled to the cooling support, which means that the complete surface of the luminescent element that faces towards the cooling support is thermally coupled to the cooling support. Thus, over a relatively large surface heat may be conducted through one of the glass layers of the sealing envelope towards the cooling support and a shortest thermal path from the luminescent material to the cooling support is through the glass layer of the sealing envelope that is in between the luminescent material and the second surface (which is a surface facing towards the cooling support). Thereby it is prevented that heat from a hotspot has to travel in a lateral direction through the sealing envelope to a location where the luminescent element is thermally coupled to the cooling support before this heat can be conducted towards the cooling support.

A first ratio of the thermal conductivity of the layers of glass and a thickness of the one of the layers of glass which is arranged between the luminescent material and the cooling support is larger than 200 W/m²K. When the first ratio is sufficiently large, the thermal resistance of the sealing envelope is sufficiently small to prevent that the sealing envelope negatively influences the spreading of heat towards the cooling support. Note that the thickness of the sealing envelope is measured along a shortest line from a surface of the sealing envelope that faces the luminescent material to an outer surface of the sealing envelope (that faces away from the luminescent material). In other words, the thickness is measured along a shortest line from the luminescent material towards the cooling support and the intersecting distance between the sealing envelope and this line is the thickness of at least that layer of glass of the sealing envelope which is arranged in between the luminescent material and the cooling support.

The luminescent element comprises a sealing envelope comprising two layers of glass which has a relatively low thermal conductivity (typically about 1.1 W/mK). It was an insight of the inventors that the difference between the first thermal conductivity and the second thermal conductivity must be sufficiently large and the first ratio sufficiently large to overcome the fact that the glass envelope is a relatively bad thermal conductor.

Optionally, the first thermal conductivity is smaller than 5 W/mK and/or the second thermal conductivity is larger than 10 W/mK. In another embodiment, the second thermal conductivity is larger than three times the first thermal conductivity. In this embodiment the difference is even larger and, thus, the heat is better redistributed along the wavelength converting element as a whole. In a further embodiment, the second thermal conductivity is larger than four times the first thermal conductivity.

The sealing envelope comprises at least two layers of glass on both sides of the luminescent material, however the sealing envelope may be totally made out of glass. It is known how to manufacture seals of glass at an affordable price with a high enough accuracy. Therefore, the solution of the above discussed wavelength converting element enables the manufacturing of relatively cheap wavelength converting elements.

An active portion of the sealing envelope, which is the portion through which light must be transmitted, is made of glass which is a light transmitting material such that the luminescent element is also light transmitting. Light transmitting means that if light impinges on one side of the sealing envelope, than at least some light is transmitted through the sealing envelope and is emitted into an ambient at another surface of the sealing envelope. In an embodiment, at least 70% of impinging light is emitted through the sealing envelope. It is to be noted that even a larger percentage may be emitted through the sealing envelope (for example, at least 80% or at least 90%) and that the light may be emitted into the ambient at all surfaces of the sealing envelope. Optionally, the sealing envelop is transparent. Optionally, the sealing envelope is translucent.

In an embodiment, the material of part of the sealing envelope is such that the sealing envelope may be closed at a relatively low temperature (e.g. by means of glue) or that the sealing envelope may be closed by only locally heating the material of the sealing envelope. Because the two layers of glass of the sealing envelope have a relatively low thermal conductivity, one may heat the two glass layers locally without ending up in a situation that this heat is conducted towards other locations of the sealing envelope thereby damaging the luminescent material. For example, one may locally heat a material that is provided in between the two layers of glass to obtain an air and moisture tight sealing envelope by using, for example, a laser beam. In this paragraph “closing” means that complete envelope is manufactured around the luminescent material thereby forming a barrier for air and moisture. In an embodiment, the luminescent material is semi-hermetically sealed in the sealing envelope, which means that a relatively low controlled amount of air and/or moisture may penetrate through the sealing envelope. In another embodiment, the luminescent material is hermetically sealed (and thus protected from air and moisture) by a glass envelope. In this embodiment no moisture or air can penetrate through the sealing envelope thereby preventing a reduction of the lifetime of the luminescent material as the result of degradation as the result of contact with air or moisture.

Furthermore, the cooling support may also have the function as a support layer which allows the manufacturing of a sealing envelope that seals the luminescent material well but is not strong enough to support itself and the luminescent material. Thus, the cooling support allows that the sealing envelope may be made relatively thin (in so far possible with respect to the sealing against air and/or moisture) and as such the sealing envelope is to a lesser extent a barrier for heat.

The sealing envelope is for protecting the luminescent material against environmental influences, such as air and/or moisture. As such, optionally, the luminescent material may be sensitive to environmental conditions, such as air and/or moisture. As will be discussed later, specific types of luminescent materials are sensitive to environmental conditions.

Optionally, the wavelength converting element forms a stack of layers, wherein the stack of layers comprises a first layer of the sealing envelope, a layer of luminescent element a second layer of the sealing envelope, an optional layer of glue, and a layer formed by the cooling support. Optionally, the order of the layers in the stack of layer is: a first layer of the sealing envelope, a layer of luminescent element a second layer of the sealing envelope, an optional layer of glue, and a layer formed by the cooling support. The second surface is formed by a surface of the second layer of glass of the sealing envelope and is a surface that faces into the direction of the optional layer of glue and/or the layer that is formed by the cooling support. The first surface is a surface of the layer that is formed by the cooling support that faces towards the optional layer of glue and/or the second layer of the sealing envelope.

Optionally, the sealing envelope provides a barrier for moisture and/or air that has a penetration rate that is smaller than 10⁻⁶ mbar l/s. If the penetration rate is smaller than 10⁻⁶ mbar l/s, the sealing envelope only allows the passage of a controlled relatively small amount of moisture and/or air. Thereby a relatively long lifetime can be obtained for the wavelength converting element. The lifetime can be further extended by including a getter in the space which is sealed by the sealing envelope (thus, to include a getter in the same space as the luminescent material is provided). In the above optional embodiment, the sealing envelope provides at least semi-hermetically seal. Gas tight is defined by a penetration rate that is smaller than 10⁻⁷ mbar l/s. Hermetically sealed, in the context of helium tests, has been defined by a penetration rate that is smaller than 10⁻⁹ mbar l/s—a seal with such a low penetration rate is termed UHV tight when the helium leakage.

Optionally, the sealing envelope comprises two layers of glass in between which the luminescent material is provided. Glass has good sealing characteristics and, thus, one may obtain a relatively good seal when the two layers of glass are used. Furthermore, it is known how to accurately and efficiently manufacture layers of glass that are suitable for this application, and, thus, the sealing envelope may have a relatively low cost price. Because of the good sealing properties of glass, the layers of glass may be relatively thin to prevent that the layers of glass are a too large barrier for heat. Optionally, when the luminescent material is provided in between two layers of glass, the sealing envelope also comprise sealing material that is provided in between the two layers of glass and is arranged around the luminescent material thereby providing a barrier for moisture and/or air. Thus, only at a relatively small area (an edge of the area at which the luminescent material is provided) this sealing material must be provided and, thus, even if the sealing material does not completely hermetically seal the luminescent material, the amount of moisture and/or air that may reach the luminescent material is relatively low. Optionally, the cooling support is also a layer and the cooling support is brought in direct contact with the one of the layers of glass thereby obtaining a good thermal coupling.

In an embodiment, the first ratio is larger than 3500 W/m²K.

Optionally, the cooling support is thermally coupled to the luminescent element via a layer of light transmitting glue. Preferably the thermal conductivity of the light transmitting glue is as high as possible, but in practical embodiments it is often not very large (e.g. smaller than 10 W/mK, or even smaller than 5 W/mK). It is to be noted that the skilled person is biased against using another layer in between the luminescent element and the cooling support which might form a thermal barrier for the heat that is generated in the luminescent element, but the inventors have found that the addition of a layer of glue with a thermal conductivity that is not very large has a limited negative influence on the conduction of heat from the luminescent element to the cooling support. Thus, even when a layer of glue is used that has a limited thermal conductivity, the use of the cooling support still results in a better heat spreading through the wavelength converting element as a whole. Optionally, a second ratio of a thermal conductivity of the light transmitting glue and a thickness of the layer of light transmitting glue is larger than 100 W/m²K. When the second ratio is sufficiently large, the thermal resistance of the light transmitting glue is sufficiently small to prevent that the total thermal resistance along the thermal path from the luminescent material to the cooling support (or even further towards a heat sink) becomes too large. In an embodiment, the second ratio is larger than 2000 W/m²K. It is assumed that the term “glue” also includes adhesives such as suitable acrylates or epoxies.

Optionally, the support layer comprises one of the materials of ceramic alumina, sapphire, spinel, AlON, SiC or MgO. These materials have good light transmitting properties and have a relatively high thermal conductivity. Optionally, the cooling support is a layer that has a thickness that is larger than 0.1 mm and is, optionally, smaller than 2.0 mm. In another embodiment, the thickness of the cooling support is larger than 0.4 mm. In a further embodiment, the thickness of the cooling support is larger than 0.7 mm.

Optionally, the wavelength converting element comprises layer of a further luminescent material being configured to absorb a portion of impinging light and to convert the absorbed portion towards light of a further color (being different from the further color of light that is generated by the luminescent material). The further luminescent material is less sensitive to environmental conditions than the luminescent material. In an embodiment, the further luminescent is not sensitive to environmental conditions, such as, for example, air and/or moisture. A function of the further luminescent material is to generate the light of the further color, but it has also an advantage that it may provide additional light scattering and may contribute to a more homogeneous light output. The layer of the further luminescent material may be provided at a surface of the luminescent element (e.g. a surface facing away from the cooling support), at a surface of the cooling support (e.g. a surface facing away from the luminescent element) and/or in between the luminescent element and the cooling support. In an embodiment, the wavelength converting element comprises an optical layer with specific optical properties (that are different from being luminescent). The optical layer may comprise scattering material, may be a filter or may comprise specific optical structures for redirecting or refracting light like outcoupling structures or micro-lenses.

Optionally, the luminescent element is configured to emit the another color of light in a narrow light emission distribution having a spectral width that is smaller than 75 nm expressed as a Full Width Half Maximum (FWHM) value. Many luminescent materials that emit light in such a relatively narrow light emission distribution are sensitive to environmental conditions, such as, moisture and/or air. Examples of such luminescent materials are particles that show quantum confinement and have at least in one dimension a size in the nanometer range. Showing quantum confinement means that the particles have optical properties that depend on the size of the particles. Examples of such materials are quantum dots, quantum rods and quantum tetrapods. Other typical narrow band luminescent materials that are sensitive to air and/or moisture are some inorganic phosphors like Thiogallates, such as, for example, Strontium Thiogallates. Other examples of inorganic phosphors that are sensitive to moisture and/or air are CaSSe and SSON:Eu. SSON:Eu is lightly moister sensitive, which means that it is less sensitive to moisture than most types of quantum dots.

According to another aspect of the invention, a light emitting module is provided which comprises a light emitter and a wavelength converting element according to any of the previously discussed embodiments of the wavelength converting element. The light emitter is configured to emit light and is arranged for emitting the light towards the wavelength converting element. The wavelength converting element is arranged to receive light from the light emitter. The light emitting module provides the same benefits as the wavelength converting element according to the above discussed aspect of the invention and has similar embodiments with similar effects as the corresponding embodiments of the wavelength converting element.

Optionally, the light emitting module also comprises a thermally conductive housing and the cooling support of the wavelength converting element is thermally coupled to the thermally conductive housing. In this optional embodiment, the cooling support forms a thermal path with a low thermal resistance to the housing of the light emitting module and, as such, in this optional embodiment, the heat may also be conducted towards the housing resulting in a better cooling of the luminescent element. Optionally, the thermally conductive housing comprises a light exit window and the wavelength converting element is arranged at the light exit window. Thus, the wavelength converting elements forms the light exit window. The light emitter is arranged to emit light towards the light exit window. An edge of the cooling support is thermally coupled to the thermally conductive housing. According to this optional embodiment, a light emitting module is obtained that can be easily integrated in luminaires and lamps and which may be coupled to a heat sink of the luminaire or lamp via the thermally conductive housing.

According to a further aspect of the invention, a luminaire is provided which comprises the wavelength converting element according to one of the above discussed embodiments, or which comprises a light emitting module according to one of the above discussed embodiments. The luminaire provides the same benefits as the wavelength converting element or the light emitting module according to the above discussed aspects of the invention and has similar embodiments with similar effects as the corresponding embodiments of the wavelength converting element or the light emitting module.

These and other aspects of the invention are apparent from and will be elucidated with reference to the embodiments described hereinafter.

It will be appreciated by those skilled in the art that two or more of the above-mentioned options, implementations, and/or aspects of the invention may be combined in any way deemed useful.

Modifications and variations of the light emitting module and/or the luminaire, which correspond to the described modifications and variations of the wavelength converting element, can be carried out by a person skilled in the art on the basis of the present description.

### BRIEF DESCRIPTION OF THE DRAWINGS

In the drawings:

FIG. 1 schematically shows three embodiments of a wavelength converting element according to an aspect of the invention,

FIGS. 2a and 2b schematically show embodiments of a light emitting module according to another aspect of the invention,

FIG. 3 schematically shows three other embodiments of wavelength converting elements in which a layer of further luminescent material is provided,

FIG. 4 schematically shows an embodiment of a wavelength converting element wherein the further luminescent material is provided in the luminescent element,

FIG. 5a schematically shows an embodiment of a lamp, and

FIG. 5b schematically shows an embodiment of a luminaire.

It should be noted that items denoted by the same reference numerals in different Figures have the same structural features and the same functions, or are the same signals. Where the function and/or structure of such an item have been explained, there is no necessity for repeated explanation thereof in the detailed description.

The Figures are purely diagrammatic and not drawn to scale. Particularly for clarity, some dimensions are exaggerated strongly.

### DETAILED DESCRIPTION

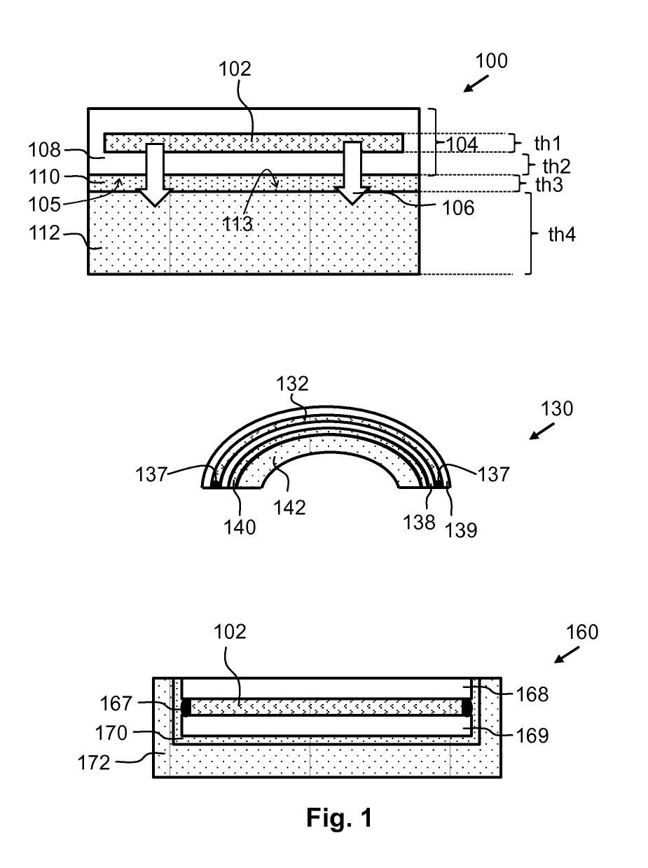

FIG. 1 schematically shows three embodiments of a wavelength converting element 100, 130, 160 according to an aspect of the invention. A first embodiment of a wavelength converting element 100 is presented at the top end of FIG. 1. The wavelength converting element 100 comprises a luminescent element 104 which comprises luminescent material 102 provided in a sealing envelope 108 made of glass. The sealing envelope 108 is thermally coupled to a cooling support 112. The thermal coupling between the sealing envelope 108 and the cooling support may be provided by, for example, a layer of glue 110. The cooling support 112 comprises a first surface 113 that faces towards the luminescent element 104. The luminescent element 104 has a second surface 105 that faces towards the cooling support 112. The second surface is formed by a surface of the sealing envelope 108. The second surface 105 is (optionally along its whole surface) thermally coupled to the first surface 113.

The luminescent material 102 is configured to absorb a portion of impinging light according to an absorption spectral distribution and convert the absorbed light towards light of another color according to a light emission spectral distribution. The luminescent material 102 is sensitive to environmental conditions, such as, air and/or moisture. Typically, luminescent materials that emit light in a relatively narrow light emission spectral distribution (meaning that the full width half maximum of that distribution is smaller than 75 nanometer) are sensitive to moisture and/or air. Examples of such luminescent materials are particles that show quantum confinement and have at least in one dimension a size in the nanometer range. Showing quantum confinement means that the particles have optical properties that depend on the size of the particles. Examples of such materials are quantum dots, quantum rods and quantum tetrapods. Other typical narrow band luminescent materials that are sensitive to air and/or moisture are some inorganic phosphors like Thiogallates, such as, for example, Strontium Thiogallates. Other materials may be CaSSe and SSON:Eu. As shown in FIG. 1, the luminescent material 102 may be provided as a layer. The layer has a certain thickness as indicated in FIG. 1 by th1. The thickness of the layer is such that a required amount of luminescent material 102 may be provided to obtain a required light conversion. The thickness is typically in a range from 0.05 mm to 1 mm. The luminescent material 102 may comprise one specific type of a luminescent material, but may also comprises a mix of different types of luminescent materials that have, for example, different light emission spectra. It might be that the luminescent material 102 is the only material present in the sealing envelope 108, but, in other embodiment, the luminescent material may be provided in a matrix, such as a matrix polymer, or, for example, in a liquid inside the sealing envelope 108.

The sealing envelope 108 is configured to and arranged for protecting the luminescent material 102 against air and/or moisture. Thus, the material of the sealing envelope 108 provides a barrier for air and/or moisture. In an embodiment, the thermal conductivity of the material of the sealing envelope 108 is lower than 5 W/mK. In another embodiment, the thermal conductivity of the material of the sealing envelope 108 is lower than 3 W/mK. In a further embodiment, the thermal conductivity of the material of the sealing envelope 108 is lower than 2 W/mK. The sealing envelope is light transmitting to allow light to be transmitted towards the luminescent material 102 and to allow the light that is generated in the luminescent material 102 to be emitted in a direction away from the luminescent material 102. A thickness of the sealing envelope 108 is made relatively small because the sealing envelope 108 would otherwise form a too large thermal barrier for heat that is generated in the luminescent material 102. A typical thickness of the sealing envelope is in a range from 200 micrometer to 1 mm. The thickness is measured in a direction from the luminescent material 102 towards the cooling support. In FIG. 1 the thickness of the sealing envelope is indicated with th2. A first ratio of the thermal conductivity of the material of the sealing envelope and a thickness th2 of the sealing envelope is larger than 200 W/m²K to prevent that the sealing envelope is a too large barrier for heat. Optionally, the first ratio is larger than 3500 W/m²K.

The sealing envelope may be manufactured for the largest part of glass. Techniques to obtain such a glass sealing envelope are, for example, glass blowing, glass welding, glass-glass frit bonding by using a laser to heat the frit, or, for example, glass-glass sealing by glue (and, optionally, using a getter within the sealed space to absorb air and/or moisture—this technology is known in the field of sealing Organic Light Emitting Diodes). Glass has a typical thermal conductivity of about 0.7 to 1.4 W/mK. Fused silica and quartz have a thermal conductivity up to 1.4 W/mK. Different types of borosilicate (including AF45 and eagle glass) have a thermal conductivity in the range from 0.9 to 1.2 W/mK. Different types of soda lime glass have a thermal conductivity in the range from 0.7 to 1.3 W/mK.

The layer of glue 110 may be used to fasten the luminescent element 104 to the cooling support 112 and to provide the thermal coupling between the luminescent element 104 and the cooling support 112. The layer of glue 110 has a thickness which is indicated in FIG. 1 with th3. The thickness of the layer of glue 110 may be relatively thin, for example, in the order of one hundred or a few hundred micrometers. The thermal conductivity of the glue is larger than 0.1 W/mK, but, in an embodiment, larger than 0.2 W/mK. Optionally, second ratio of a thermal conductivity of the light transmitting glue and a thickness th3 of the layer of light transmitting glue is larger than 100 W/m²K to prevent that the layer of glue 110 has a too large thermal resistance. Optionally, the second ratio is larger than 2000 W/m²K. The layer of glue 110 is also light transmitting to allow a transmission of light from the cooling support 112 to the luminescent element 104 and vice versa. Because the layer of glue 110 may become relatively warm, the glue should be stable, for example, the glue may be LED grade material, which means that it is stable at elevated temperatures and high fluxes of incident light, for example, high fluxes of incident blue light. Stable at least means that no optical degradation occurs and that there is about no delamination of the two components that are glued to each other. For example, Silicone KJR9222 and KJR9224 (Shin-Etsu) or Lumisil 400 (Wacker) have been tested as glues that have such characteristics. Other adhesives that could be used are suitable acrylates or epoxies, such as, for example, the Delo-family (Katiobond).

It is schematically drawn by means of arrow 106 that heat that is generated by the luminescent material 102 may be well conducted towards the cooling support 112 as long as a thermal resistance of a thermal path through the sealing envelope 108 and the layer of glue 110 is relatively low. By choosing appropriate materials the glue, and choosing appropriate layer thicknesses for the glass sealing envelope 108 and the layer of glue 110, a relatively large amount of heat generated in the luminescent material 102 may be conducted towards the cooling support 112. The cooling support 112 redistributes the heat such that a more uniform temperature distribution is obtained through the wavelength converting element 100.

The cooling support 112 is made of a light transmitting material and has a relatively high thermal conductivity. In an embodiment, the thermal conductivity of the material of the cooling support 112 is larger than 10 W/mK, or, in another embodiment, larger than 15 W/mK, or, in a further embodiment, larger than 20 W/mK. The thickness of the cooling support is indicated in FIG. 1 by th4. The thickness th4 is sufficient large such that a large amount of heat may be transported by the cooling support 112, but not too large so that it does not introduce a too big thermal resistance in the heat path from the luminescent material to a potential heat sink. The thickness th4 is, for example, larger than 0.1 mm, or, in another embodiment, larger than 0.5 mm, or in a further embodiment, larger than 0.8 mm. The thickness th4 of the cooling support is, for example, smaller than 2 mm. Thereby the cooling support strongly contributes to the redistribution of heat within the whole wavelength conversion element 100 such that no relatively warm hotspots are present while other parts of the wavelength conversion element 100 are relatively cool.

Other adhesives that could be used are suitable acrylates or epoxies, such as, for example, the Delo-family (Katiobond). via the glue 112 also contributes to the fact that heat is better conducted towards an environment of the wavelength conversion element 100. Useful materials for the cooling support are ceramic Alumina, sapphire, spinel, AlON, SiC, MgO.

In FIG. 1 the presented embodiments are drawn in cross-sectional view. The presented cross-sectional view of wavelength converting element 100 may be a cross section of a disk shaped wavelength converting element 100, or a square or rectangular box shaped wavelength converting element 100. As such, the three dimensional shape of the luminescent element 104 and/or of the cooling support 112 may also be one of disk shaped or square or rectangular box shaped. In practical embodiments, the cooling support 112 forms a layer and the luminescent material 102 is also provided in a layer between two layers of glass.

Wavelength converting element 130 has a different cross-sectional view. Except for the shape of the wavelength converting element 130 and the embodiment of the sealing envelope of the wavelength converting element 130, wavelength converting element 130 is similar to the above discussed wavelength converting element 100. The presented cross-sectional shape has the shape of half an ellipse (or, in another embodiment, half a circle). This means that the three dimensional shape of the wavelength converting element 130 may be a shape of a dome or a shape of a tunnel. This implies that the luminescent element and the cooling support 142 have also such a shape. The embodiment of the luminescent element of wavelength conversion element 130 comprises two dome shaped or tunnel shaped layers of glass 138, 139 in between which a layer of the luminescent material 132 is provided. At an edge of the layer of luminescent material 132 an opening between the two layers of glass 138, 139 is sealed by a sealing material 137. The sealing material 137 may be a dedicated type of glue which forms a relatively good barrier for moisture and/or air. The sealing material 137 may also be based on glass and may be welded to the two layers of glass 138, 139 by locally heating the material and the neighboring glass. Such local heating may be obtained by impinging a relatively small, but powerful, laser bundle to the location where the sealing material 137 must be welded to the two layers of glass 138, 139. In between one of the layer of glass 138, 139 and the cooling support 142 a layer of light transmitting glue 140 is provided. Embodiments of the glue, the luminescent material 132 and further characteristics of the elements of the wavelength conversion element 130 are discussed in the context of wavelength conversion element 100.

At the bottom end of FIG. 1 another embodiment of a wavelength conversion element 160 has been presented. Except for the shape of the cooling support 172 and the embodiment of the sealing envelope, the wavelength conversion element 160 is similar to wavelength conversion element 100. In line with wavelength conversion element 130, the sealing envelope comprises two layers of glass 168, 169. The two layers of glass 168, 169 have a relatively flat shape and may be disk shaped, square or rectangular shaped, or have any other appropriate flat shape. The luminescent material 102 is provided in between the two layers of glass 168, 169 and at an edge of the luminescent material 102 (close to the edges of the two layers of glass 168, 169) the space in between the two layer of glass 168, 169 is sealed by means of sealing material 167 (of which embodiments have already been discussed above). The wavelength conversion element 160 further comprises a (circular or rectangular) tray shaped cooling support 172. The luminescent element that is formed by the two layer of glass 168, 169, the luminescent material 102 and the sealing material 167 is provided inside the tray shaped cooling support 172. The luminescent element is glued by means of a layer of light transmitting glue 170 to the cooling support 172. In this embodiment, a better thermal coupling is obtained between the luminescent element and the cooling support because a larger portion of the luminescent element is via the blue in contact with the cooling support. Embodiments of the glue, the luminescent material 102 and further characteristics of the elements of the wavelength conversion element 160 are discussed in the context of wavelength conversion element 100.

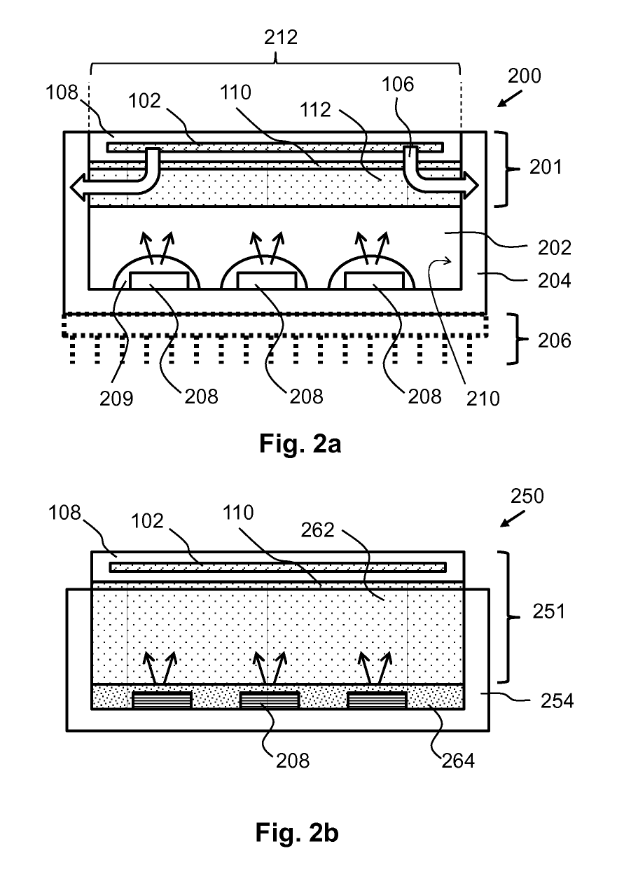

FIGS. 2a and 2b schematically show embodiments of a light emitting module 200, 250 according to another aspect of the invention. FIG. 2a shows light emitting module 200 which comprises a wavelength converting element 201 which may be similar to wavelength converting element 100 or 160 of FIG. 1. Light emitting module 200 further comprises a thermally conductive housing 204 and comprises one or more light emitters 208. The thermally conductive housing 204 encloses a space 202 which is, for example, filled with air. The inner walls 210 of the thermally conductive housing 204 that are facing towards the space 202 may be provided with a light reflective coating or layer (not shown) such that light that impinges on the inner walls 210 is reflected instead of absorbed. Within the space 202 are provided the one or more light emitters 208. Optionally the light emitters 208 are provided with a dome shaped optical element 209 which, for example, contributes to a good light extraction from the light emitters 208 and/or which may refract the light emitted by the light emitters 208 such that a wider light beam is emitted by the light emitters 208. At one side of the thermally conductive housing a light exit window 212 is provided. At the light exit window 212 is provided the wavelength converting element 201. At least an edge of the cooling support 112 is thermally coupled to the thermally conductive housing 204. This thermal coupling may be obtained by, for example, a thin layer of glue (which has a sufficient high thermal conductivity, but in practical embodiments, the thermal conductivity of the glue is not really high). The cooling support 112 may also be arranged in direct contact with the thermally conductive housing 204. As shown in FIG. 2a, edges of the sealing envelope 108 may also be directly in contact with the thermally conductive housing 204 or the edges of the sealing envelope 108 are also thermally coupled to the thermally conductive housing 204 by means of a thin layer of glue. By means of arrow 106 it is schematically indicated how heat may be conducted from the luminescent material 102, via the sealing envelope 208, the layer of glue 110 and the cooling support 112 towards the thermally conductive housing 204.

In an embodiment, walls of the thermally conductive housing 204 may also have a lower part that is relatively thick and may have an upper part that be relatively thin (the upper part is a portion that is close to the light exit window 212) such that the walls of the thermally conductive housing have a profile in which the wavelength converting element 201 fits (which means, in which the wavelength converting element 201 may be laid/glued). Thereby a portion of a surface of the cooling support 112, which faces towards the space 202, is also in contact with an upper part of the thermally conductive wall to obtain a better thermal coupling.

As shown in FIG. 2a, the light emitting module 200 may optionally have a heat sink 206. The heat sink 206 may be thermally coupled to a surface of the thermally conductive housing 204 that is facing away from the space 202 (and, in particular, in FIG. 2a a surface that is opposite a surface on which the light emitters 208 are provided). The thermally conductive housing 204 may conduct heat that it received from the wavelength converting element towards the heat sink 206.

In FIG. 2a it has been drawn that the cooling support 112 faces the space 202 in which the light emitters 208 are provided. In another embodiment, the wavelength converting element 201 may also arranged up-side-down in the thermally conductive housing 204 such that the cooling support layer faces the ambient and a portion of the sealing envelope faces the space 202.

In FIG. 2a three light emitters 208 have been drawn. Embodiments of the light emitting module may comprise one, two, three or more light emitters 208. In an embodiment the light emitters are solid state light emitters. For example, the light emitters 208 are Light Emitting Diodes (LEDs). The light emitters 208 may emit blue light and the luminescent material(s) 102 of the wavelength converting element may be configured to convert a portion of the received blue light towards yellow light such that a combination of yellow light and blue light may result in a white light emission. The luminescent material(s) 102 may also be configured to convert a portion of the blue light towards red light such that the light emitted by the light emitting module 200 comprises a more smooth light emission distribution and may have a higher Color Rendering Index (CRI). It is to be noted that embodiments of the luminescent materials 102 are not limited to yellow or red emitting luminescent materials.

In FIG. 2b another embodiment of a light emitting module 250 has been presented. The light emitting module 250 comprises a thermally conductive housing 254 which encloses a cavity and inside this cavity are provided light emitters 208. The walls of the cavity may be provided with a light reflective coating or layer. The light emitting module 250 also comprises wavelength converting element 251 which is similar to wavelength converting elements 100, 160 of FIG. 1 except that the cooling support 262 is relatively thick and fills for the largest part the cavity that is enclosed by the thermally conductive housing 254. In an embodiment, the cooling support 262 may be in direct contact with the light emitters 208 such that light emitted by the light emitters 208 is well coupled into the cooling support 262. In another practical embodiment, a light transmitting medium 264, for example, Silicone, is provided in between the light emitters 208 and the cooling support 262. The light transmitting medium 264 assist in the outcoupling of light from the light emitters 208 and allows the transmission of the light towards and into the cooling support 262. The cooling support 262 is along a relatively large surface in thermal contact with the thermally conductive housing 254 such that a relatively large portion of the heat that is received from the luminescent material 102 may be conducted towards the thermally conductive housing 254. As shown in FIG. 2b, it is not necessary that the luminescent element with sealing envelope 108 and luminescent material 102 is arranged in between walls of the thermally conductive housing 254—the luminescent element may protrude out of the thermally conductive housing 254.

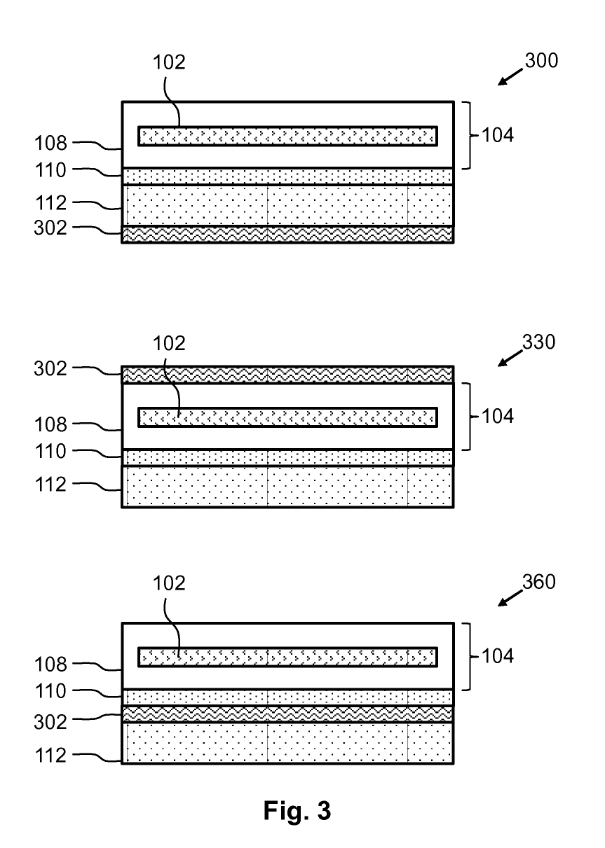

FIG. 3 schematically shows three other embodiments of a wavelength converting elements 300, 330, 360 in which a layer of further luminescent material is provided. Basically, the arrangement of the wavelength converting element 300, 330, 360 is similar to the arrangement of wavelength converting elements 100, 160 of FIG. 1 except that an additional layer 302 of further luminescent material is provided. The further luminescent material is to a lesser extent sensitive to air and/or moisture than the luminescent material 102 is and, as such, the further luminescent material is not sealed and protected against air and/or moisture. The further luminescent material is configured to absorb a portion of impinging light and convert the absorbed portion towards light of a further color. For example, the further luminescent material may be a yellow/orange emitting inorganic phosphor (e.g. YAG:Ce (for example, NYAG) or LuAG:Ce). Often these further luminescent materials have a relatively broad light emission spectrum. In the different embodiments of the wavelength converting element 300, 330, 360 the additional layer 302 of the further luminescent material is arranged at different positions. In wavelength converting element 300, the additional layer 302 of the further luminescent material is arranged at a surface of the cooling support 112 that is opposite a surface of the cooling support 112 that is thermally coupled to the luminescent converter 104. In wavelength converting element 330, the additional layer 302 of the further luminescent material is arranged at a surface of the luminescent converter 104 that is opposite a surface of the luminescent converter 104 that is thermally coupled to the cooling support 112. In wavelength converting element 360, the additional layer 302 of the further luminescent material is arranged in between the cooling support 112 and the luminescent converter 104.

In another embodiment, layer 302 is an optical layer with specific optical properties (that are different from being luminescent). The optical layer may comprise scattering material, may be a filter or may comprise specific optical structures for redirecting or refracting light like outcoupling structures or micro-lenses. It is to be noted that such an optical layer may also be combined with the additional layer of further luminescent material.

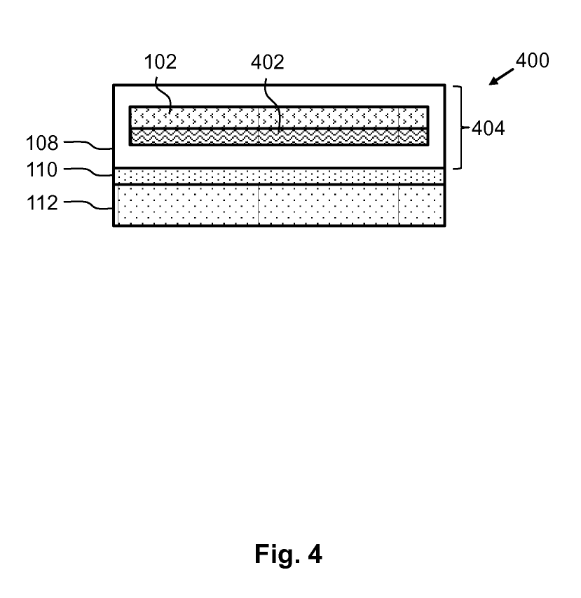

FIG. 4 schematically shows an embodiment of a wavelength converting element 400 wherein the further luminescent material 402 is provided in the luminescent element 404. Except the addition of the further luminescent material 402, the wavelength converting element 400 is similar to wavelength converting elements 100, 160 of FIG. 1. Although it is not required to seal the further luminescent material (as discussed in the context of FIG. 3), this further luminescent material 402 may be provided within the sealing envelope 108 together with the luminescent material 102 that is sensitive to air and/or moisture. In FIG. 4 two distinct layers, each one with one of the luminescent materials 102, 402, are drawn inside the sealing envelope 108, but, in other embodiment, the different luminescent materials 102, 402 may be provided as a mix inside the sealing envelope 108.

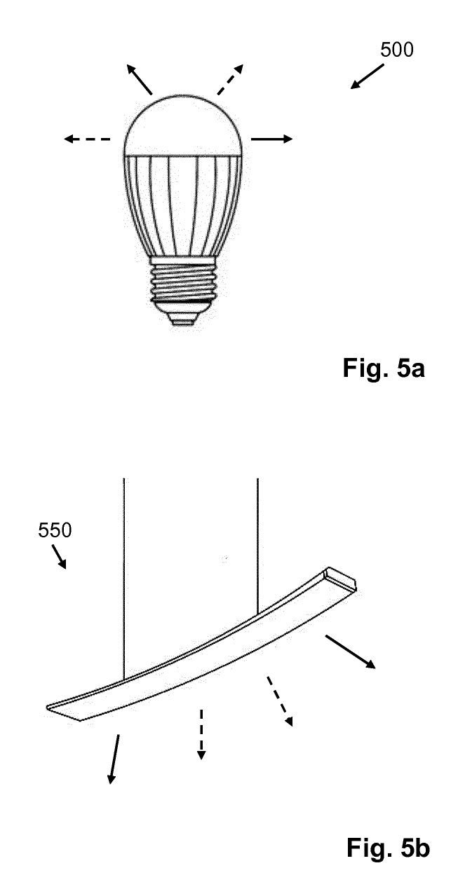

FIG. 5a schematically shows an embodiment of a lamp 500. The lamp 500 has, for example, a shape of a traditional incandescent lamp and is, as such, a retro-fit incandescent lamp. The lamp 500 may comprise, for example, one or more light emitting modules (not shown) according to previously discussed embodiments of the light emitting modules or the lamp 500 may comprise one or more wavelength conversion elements (not shown) according to previously discussed embodiments of the wavelength converting elements.

FIG. 5b schematically shows an embodiment of a luminaire 550. The luminaire 550 comprises, for example, one or more light emitting modules (not shown) according to previously discussed embodiments of the light emitting modules. In another embodiment, the luminaire 550 comprises one or more lamps (not shown) according to the embodiment of FIG. 5a. In yet a further embodiment, the luminaire 550 comprises one or more wavelength conversion elements (not shown) according to previously discussed embodiments of the wavelength converting elements.

In summary, a wavelength converting element, a light emitting module and a luminaire are provided. The wavelength converting element comprises a luminescent element and a light transmitting cooling support. The luminescent element comprises a luminescent material and a light transmitting sealing envelope for protecting the luminescent material against environmental influences. The sealing envelope has a first thermal conductivity. The cooling support has a second thermal conductivity that is at least two times the first thermal conductivity. The cooling support comprises a first surface and the sealing envelope comprises a second surface. The first surface and the second surface face towards each other. The first surface is thermally coupled to the second surface for allowing through the second surface a conduction of heat towards the cooling support to enable a redistribution of the heat generated in the luminescent element.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The mere fact that certain measures are recited in mutually different dependent claims does not indicate that a combination of these measures cannot be used to advantage.

1. A wavelength converting element comprising:
a luminescent element comprising a luminescent material and a sealing envelope,
the luminescent material being configured to absorb a portion of impinging light and to convert a portion of the absorbed light towards light of another color, the luminescent material being provided in the sealing envelope,
the sealing envelope comprising two layers of glass in between which the luminescent material is provided, the sealing envelope being light transmitting, having a first thermal conductivity and being configured to protect the luminescent material against environmental influences,
a cooling support made of a light transmitting material having a second thermal conductivity that is larger than two times the first thermal conductivity,
wherein the cooling support comprises a first surface, the sealing envelope comprises a second surface, the first surface faces towards the second surface, and the first surface is thermally coupled to the second surface for allowing through the second surface a conduction of heat towards the cooling support to enable a redistribution of the heat generated in the luminescent element, wherein a first ratio of the thermal conductivity of the layers of glass and a thickness of the one of the layers of glass which is arranged between the luminescent material and the cooling support is larger than 200 W/m²K,
wherein the cooling support is thermally coupled to the luminescent element via a layer of light transmitting glue, wherein a second ratio of a thermal conductivity of the light transmitting glue and a thickness of the layer of light transmitting glue is larger than 100 W/m²K.

2. A wavelength converting element according to claim 1, wherein
the first thermal conductivity is smaller than 5 W/mK, or
the second thermal conductivity is larger than 10 W/mK, or
the first thermal conductivity is smaller than 5 W/mK and the second thermal conductivity is larger than 10 W/mK.

3. A wavelength converting element according to claim 1, wherein the sealing envelope provides a barrier for moisture and/or air that has a penetration rate that is smaller than 10⁻⁶ mbar l/s.

4. A wavelength converting element according to claim 1, wherein the sealing envelope comprises sealing material provided in between the two layers of glass and arranged around the luminescent material, the sealing material being configured to provide a barrier for moisture and/or air.

5. A wavelength converting element according to claim 1, wherein the first ratio is larger than 3500 W/m²K.

6. (canceled)

7. (canceled)

8. A wavelength converting element according to claim 1, wherein the cooling support comprises one of the materials alumina, sapphire, spinel, AlON, SiC or MgO.

9. A wavelength converting element according to claim 1, wherein the cooling support is a layer and a thickness of the layer is larger than 0.1 mm and optionally smaller than 2.0 mm.

10. A wavelength converting element according to claim 1 comprising a layer of a further luminescent material being configured to absorb a portion of impinging light and to convert the absorbed portion towards light of a further color, the further luminescent material being less sensitive to environmental influences than the luminescent material.

11. A wavelength converting element according to claim 1, wherein the luminescent material is configured to emit the another color of light in a narrow light emission distribution having a spectral width of not more than 75 nm expressed as a Full Width Half Maximum Value.

12. A light emitting module comprising:
a light emitter for emitting light,
a wavelength converting element according to claim 1, the wavelength converting element being arranged to receive light from the light emitter.

13. A light emitting module according to claim 12, wherein the light emitting module also comprises a thermal conductive housing and the cooling support of the wavelength converting element is thermally coupled to the thermal conductive housing.

14. A light emitting module according to claim 13, wherein the thermal conductive housing comprises a light exit window, the light emitter is arranged to emit light towards the light exit window, the wavelength converting element forms the light exit window and an edge of the cooling support being thermally coupled to the thermal conductive housing.

15. A luminaire comprising a wavelength converting element according to claim 1.

16. A luminaire comprising a light emitting module according to claim 12.
